(19) United States
(12) Patent Application Publication
(10) Pub. No.: US 2026/0344108 A1
(43) Pub. Date: Oct. 29, 2026

(54) PHOTOVOLTAIC-THERMAL MODULE

(71) Applicant: Sunmaxx PVT GmbH, Ottendorf-Okrilla (DE)

(72) Inventor: Wilhelm Stein, Dresden (DE)

(21) Appl. No.: 19/111,712

(22) PCT Filed: Aug. 23, 2023
(86) PCT No.: PCT/EP2023/073146

§ 371 Date: Mar. 13, 2025

(30) Foreign Application Priority Data
Sep. 19, 2022 (DE) 10 2022 123 915.2

(51) Int. Cl. H10F 77/63; F24S 10/50

(52) U.S. Cl. CPC H10F 77/68; F24S 10/50

(57) ABSTRACT

In an embodiment a photovoltaic-thermal module includes a plurality of solar cells and a planar heat sink based on at least one inorganic material and including a plurality of cooling channels, wherein the planar heat sink includes two plates between which the cooling channels are located, wherein a first plate of the plates, facing the solar cells, is flat, wherein the cooling channels are defined by a second plate of the plates, the second plate facing away from the solar cells, and wherein the second plate is arranged on a main surface of the first plate such that a first region of the first plate is covered by the second plate and a second region of the first plate is free of the second plate.

### CROSS-REFERENCE TO RELATED APPLICATIONS

This patent application is a national phase filing under section 371 of PCT/EP2023/073146, filed Aug. 23, 2023, which claims the priority of German patent application no. 102022123915.2, filed Sep. 19, 2022, each of which is incorporated herein by reference in its entirety.

### TECHNICAL FIELD

A photovoltaic-thermal module is disclosed.

### BACKGROUND

The publication WO 2015/184402 relates to a photovoltaic module with an integrated liquid cooling system.

### SUMMARY

Embodiments provide a photovoltaic-thermal module that can be efficiently manufactured and operated economically. Embodiments of the disclosure relate to a photovoltaic-thermal module.

According to at least one embodiment, the photovoltaic-thermal module, or PVT module for short, comprises a plurality of solar cells. The solar cells are based, for example, on silicon and/or on germanium and/or on a compound semiconductor material such as CdTe or CuInGaS, or CIGS for short, or CuInS, or CIS for short. Solar cells can also be based on perovskite or at least one organic, photoactive material. In thin-film modules, particularly those based on CdTe, CIGS, CIS, amorphous Si or perovskite, the photoactive layers are preferably arranged in stripes, for example with a width of at least 3 mm and/or at most 3 cm.

It is possible that several different types of solar cells or semiconductor materials are combined in the PVT module to achieve greater efficiency. For example, the individual, for example crystalline, solar cells comprise a mean diameter of at least 5 cm or at least 10 cm and/or at most 50 cm. The mean diameter D is calculated from an area A of the solar cell, for example, as follows D=(4A/π)0,5.

It is also possible that the cells are halved or thirded and so on or cut into strips. Thus, the crystalline solar cells are then not squares or pseudo-squares, but rectangles.

According to at least one embodiment, the PVT module comprises one or more planar heat sinks. The heat sink, which may be the only one present, can also be referred to as a cooling plate or a backside cooling unit. The planar heat sink is based on at least one inorganic material, such as a glass or a metal, for example aluminum. The term ‘based on at least one inorganic material’ means, for example, that at least 80% by weight, or at least 90% by weight, or at least 98% by weight, of the planar heat sink is formed by the at least one inorganic material. This does not preclude small components of the planar heat sink, in particular non-mechanically load-bearing components such as seals or labels, from being formed from organic materials.

According to at least one embodiment, the planar heat sink comprises a plurality of cooling channels. The cooling channels are designed to have a cooling liquid flowing through them.

The planar heat sink extends, for example, continuously over the respective solar cells or parts of solar cells. For example, all solar cells of the PVT module are coupled to a single common planar heat sink, which is, for example, free of gaps or holes.

The planar heat sink comprises at least two plates between which the cooling channels are formed. This makes it possible for the planar heat sink to be a self-contained, sealed system that is suitable for the cooling liquid to flow through without the need for any additional components. In particular, the cooling channels are completely defined by the plates, optionally together with a connector between the plates and/or for holding the plates together.

The heat sink plates are each formed, for example, by metal plates, for example by aluminum plates. Alternatively, the heat sink plates are formed by glass plates, so that the planar heat sink can be translucent. It is also possible to form the plates from plastic and/or foils.

A first one of the plates, which faces the solar cells, is flat. The cooling channels are defined by a second one of the plates, which faces away from the solar cells. The cooling channels can therefore be formed in the second plate.

The second plate is arranged on a main surface of the first plate. A first region of the first plate is thus covered by the second plate. A second region of the first plate is free of the second plate. In particular, an edge region of the first plate is free of the second plate. For example, the first plate extends completely over the solar cells. The second plate extends only partially over the solar cells. For example, the first plate is attached to at least 80% or at least 90% or at least 95% of the area of all solar cells combined. The second plate is attached to a correspondingly smaller area of all solar cells combined, so that an edge area of the first plate remains free and is not covered by the second plate. For example, the first plate extends over a larger area than the second plate. For example, the second region comprises a width of several millimeters, for example more than 5 mm, for example a width between 5 mm and 15 mm, in particular, for example, approximately 10 mm.

Thus, it is possible to configure the second region free of cooling channels. Thus, for example, mechanical attachment points can be configured on the second region of the planar heat sink, in particular for connecting individual elements of the PVT module or for attaching further elements such as fastening elements or clamping elements. Damage to the cooling channels in the edge region can thus be avoided. Nevertheless, it is possible to design a reliable connection between the two plates and the cooling channels can extend over almost the entire surface of the second plate. In particular, it is possible to design the cooling channels up to the edge of the second plate, so that, for example, only a maximum of 3 to 4 mm at the edge of the second plate is designed without cooling channels. This enables a comparatively simple production of the planar heat sink when connecting the two plates. Alternatively or additionally, this enables a reliable connection of the two plates. For example, the two plates are connected to each other by a soldered connection so that the second plate is held reliably to the first plate.

According to at least one embodiment, the second region surrounds the first plate all around the second plate. The planar heat sink thus comprises the second region in the manner of a frame. The second region, which is free of the second plate, is thus formed on all four longitudinal sides of the rectangular planar heat sink. It is also possible that the second region is configured only on some of the four longitudinal sides, for example on only two opposite longitudinal sides.

According to at least one embodiment, the PVT module comprises a support frame. The support frame is configured to mechanically support the PVT module. The support frame is in contact with the second region of the first plate. In particular, the support frame also serves to additionally support the bond between the solar cells and the planar heat sink. In the second region, where no cooling channels are configured, it is possible to press the first plate and the solar cells together with the support frame. The PVT module is thus clamped in the support frame. In particular, the smaller second plate is not in direct contact with the support frame. This prevents the cooling channels from being damaged or influenced by the mechanical forces of the support frame.

The support frame is configured in particular to clamp the solar cells and the first plate together. This additionally supports the connection between the solar cells and the planar heat sink. For example, the solar cells and the first plate are connected to one another by a lamination film. This connection is additionally mechanically supported by the support frame.

According to further embodiments, the planar heat sink comprises two plates between which the cooling channels are formed. A first one of the plates faces the solar cells and a second one of the plates faces away from the solar cells. The cooling channels are defined by the second of the plates. The first plate comprises a foil or a varnish.

For example, the first plate is formed by a foil or a varnish. For example, the first plate is formed by an inorganic foil, for example made of PET (polyethylene terephthalate) or another plastic. Alternatively or additionally, the first plate is formed from a varnish, for example a clear varnish. The varnish is, for example, sprayed onto the solar cells.

The first plate made of foil or varnish also serves as electrical insulation for the solar cells, for example, as electrical insulation for the second plate with respect to the solar cells.

The planar heat sink is comparatively easy to manufacture and comprises less weight than a planar heat sink made of two metal plates. A reliable connection of the two plates can also be realized without a soldering process. In particular, it is also possible to make the two plates the same size or almost the same size, so that both plates essentially cover the same area of the solar cells.

According to at least one embodiment, the foil and the second plate are connected to each other by an adhesive bond. The planar heat sink thus comprises, for example, a PET-aluminum adhesive bond. It is also possible to provide the second plate made of glass so that the planar heat sink comprises, for example, a PET-glass adhesive bond. Alternatively or additionally, the planar heat sink comprises the varnish, which is additionally provided in the composite, for example. It is also possible that the varnish is provided instead of the foil, so that the planar heat sink comprises the varnish-aluminum composite or varnish-glass composite.

According to at least one embodiment, the foil is arranged directly on the solar cells. The foil thus serves both to close and seal the cooling channels and to attach the planar heat sink to the solar cells. The foil is thus in direct contact with the solar cells and also with the second plate.

Alternatively or additionally, the varnish can be used to embed the solar cells so that they are held by the varnish. In this case, the varnish serves, for example, as a stabilizer and carrier for the solar cells and at the same time as a cover and connection for the second plate. Additional lamination films are not required in this design. During production, a lamination step is no longer necessary.

According to at least one embodiment, the PVT module comprises a front coating that is arranged on a side of the solar cells facing away from the planar heat sink and that covers the solar cells. The front coating is formed by a foil or a varnish. The front coating replaces, for example, a front glass. The front coating faces the sun during operation and is permeable to radiation. The front coating is significantly lighter than front glass. For example, the front coating is formed from the varnish in which the solar cells are embedded. It is also possible to use different varnishes, for example, a first varnish for embedding the solar cells and for bonding to the second plate, and a further varnish as a front coating.

According to at least one embodiment, the PVT module comprises a layer stack. In a stacking direction, the layer stack comprises: the second plate, which defines the cooling channels; the varnish, which is configured as a layer and in which the solar cells are embedded; the front coating, which covers the varnish. In particular, the layer stack does not comprise any other significant elements, in particular no front glass on the side of the solar cells facing away from the second plate and no lamination film.

According to further embodiments, the PVT module comprises the planar heat sink, which has two plates between which the cooling channels are formed. The first one of the plates faces the solar cells and the second one of the plates faces away from the solar cells. The second one of the plates defines the cooling channels. The first plate, which faces the solar cells, is flat. The first plate and the second plate are each based on at least one inorganic material, such as a glass or a metal, for example aluminum. The PVT module comprises a varnish layer in which the solar cells are embedded. The planar heat sink is attached to the varnish layer. Optionally, a plastic film can be arranged between the planar heat sink and the varnish layer for electrical insulation. In particular, the PVT module comprises the front coating, which is arranged on the side of the solar cells facing away from the planar heat sink and covers the solar cells, wherein the front coating is formed by a foil or a varnish.

For example, the first plate is based on an inorganic material, in particular aluminum or glass. A foil and/or a varnish, which is provided in addition to the inorganic material, serves in particular as an intermediate layer between the varnish in which the solar cells are embedded and the inorganic plate of the planar heat sink. The first plate comprises the foil on a side facing away from the second plate. The foil, which is for example a PET foil, is attached to the varnish. The foil serves as electrical insulation between the planar heat sink and the solar cells.

### BRIEF DESCRIPTION OF THE DRAWINGS

Further advantages, features and developments are explained below with reference to the drawings. The same reference signs indicate the same elements in the individual figures. The representations are not to scale; individual elements may be shown exaggeratedly large for better understanding.

FIG. 1 shows a schematic cross-section of a PVT module according to an embodiment;

FIG. 2 shows a schematic cross-section of a PVT module according to an embodiment;

FIG. 3 shows a schematic cross-section of a PVT module according to an embodiment; and

FIG. 4 shows a schematic cross-section of a PVT module according to an embodiment.

### DETAILED DESCRIPTION OF ILLUSTRATIVE EMBODIMENTS

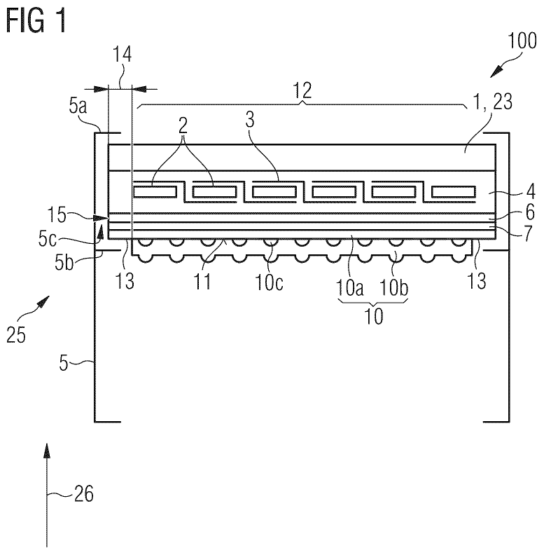

A photovoltaic-thermal module 100, or PVT module for short, combines photovoltaic modules for generating electricity with the use of the waste heat from the modules. PVT modules thus convert solar energy into electricity and the waste heat produced in the process is made usable. In addition to electrical energy, such PVT modules also produce heat, for example in the form of hot water or other cooling liquids. An example of such a PVT module is shown in FIGS. 1 to 3. Examples of the basic functioning and areas of application of the PVT modules described here are described in German patent application 10 2021 123 000.4.

FIG. 1 shows a sectional view of an embodiment of the photovoltaic-thermal module 100, also referred to as a PVT module for short. The PVT module 100 comprises a front glass 1. A planar heat sink 10 is located on an opposite side of the front glass 1. A plurality of solar cells 2, for example crystalline solar cells, are connected to one another via electrical cell connectors 3 and arranged between the front glass 1 and the planar heat sink 10. In particular, the solar cells 2 with the electrical cell connectors 3 are embedded in a lamination film 4, for example in an EVA film. The lamination film 4 is located on the front glass 1.

On a side of the lamination film 4 opposite the front glass 1, there is a rear wall 6, in particular a rear wall film, for example a polyvinyl fluoride film, or PVF film for short, such as a Tedlar film, or alternatively a rear glass. The planar heat sink is glued or laminated onto the rear wall 6, for example by an adhesion layer 7. The adhesion layer 7 is formed, for example, from an adhesive or from a further EVA foil. By the adhesion layer 7, the planar heat sink 10 is attached to the so-called PV module or PV laminate.

The PVT module 100 comprises a frame 5. The frame 5, for example made of aluminum, mechanically supports the PVT module 100, in particular the PV laminate and the planar heat sink 10.

The frame 5 has an upper bracket 5a and a lower bracket 5b, which for example each project horizontally. A clamp connection 5c is configured by the upper bracket 5a and the lower bracket 5b. By the clamp connection 5c, a layer stack 25 is compressed and clamped along a stacking direction 26. The layer stack 25 comprises, in particular, the front glass 1 and the planar heat sink 10, as well as the layers arranged therebetween, which are arranged one on top of the other along the stacking direction 26.

The planar heat sink 10 comprises, in particular, two thin aluminum sheets 10a, 10b that are connected to one another. For example, a channel structure having a plurality of cooling channels 10c is stamped in one of the two plates 10b by a stamping process. This channel structure consists of many branches and is optimized to dissipate heat as efficiently as possible and to enable the lowest possible pressure losses.

The second plate 10b with the cooling channels 10c is connected to the first plate 10a using a soldering process. The second plate 10b is arranged on a main surface 11 of the first plate 10a facing away from the solar cells 2. The main surface 11 comprises a larger extent than the side surfaces or edge surfaces of the first plate 10a, which are arranged transversely thereto.

The second plate 10b is arranged in a first region 12 of the first plate 10a. The first region 12 is, in particular, a central region of the first plate 10a. The first region 12 is laterally surrounded by a second region 13. The second region 13 is not covered by the second plate 10b. The second plate 10b is arranged only in the central first region 12 and is in particular spaced apart from an edge 15 of the layer stack 25.

Between the lateral edge 15, which in the sectional view runs along the stacking direction 26, and the second plate 10b, the second region 13 is provided transversely with respect to the stacking direction 26, at which the first plate 10a is in particular not covered. The second plate 10b thus comprises a distance 14, which is measured transversely to the stacking direction 26 along the main surface 11. For example, the distance 14 is in a range from more than 5 mm up to 20 mm, in particular between 7 mm and 15 mm, in particular between 9 and 11 mm, for example 10 mm. The second plate 10 b is arranged laterally at a distance of 14 from the edge 15.

The first plate 10a covers the solar cells 2 flat over the surface, in particular completely or almost completely. The second plate 10b is configured to be smaller in comparison. In particular, the surface covered by the second plate 10b is smaller than the surface covered by the first plate 10a.

The frame 5 is in contact with the planar heat sink 10 in the second region 13. The frame 5 contacts the first plate 10a in the second region 13. The second plate 10b is not directly touched by the frame 5. The clamp connection 5c is formed between the first plate 10a and the front glass 1. The second plate remains unaffected by mechanical loads that are applied directly by the lower bracket 5b. To this end, the second plate 10b is smaller than the first plate 10a, so that the second region 13 is formed. The clamp connection 5c is thus configured with the first plate 10a, which does not comprise any cooling channels 10c but is configured to be flat in particular.

The second plate 10b, which comprises the cooling channels 10c, can be attached to the first plate 10a without the direct action of the clamp connection 5c. This enables a particularly reliable connection between the first plate 10a and the second plate 10b by a solder. The cooling channels 10c can be distributed as desired on the second plate 10b and, in particular, can also be routed close to a lateral edge, which is beneficial for the reliable solder connection. This helps to avoid damaging the cooling channels 10c with the clamp connection 5c, in particular the lower bracket 5b.

The first plate 10 a is approximately 10 mm larger all around the second plate 10 b, for example. This makes it possible to insert the first plate 10a into the gap in the frame 5 between the upper bracket 5a and the lower bracket 5b. The second plate 10b does not come into conflict and/or contact with the frame 5. Due to the reliable solder connection between the two plates 10a, 10b, the fact that the second plate 10b is not inserted into the gap between the upper bracket 5a and the lower bracket 5b does not affect the stability.

Clamping the first plate 10a in the gap of the frame 5 additionally strengthens the connection between the first plate 10a and the PV laminate, in addition to the adhesion layer 7. The PV laminate and the planar heat sink 10 are pressed and compressed by the frame, in particular by the upper bracket 5a and the lower bracket 5b. The first plate 10a is pressed by the lower bracket 5b in the direction of the front glass 1. The planar heat sink 10 can be inserted with the first plate 10a into the gap between the upper bracket 5a and the lower bracket 5b of the frame 5. This accomplishes an additional fixing process in addition to gluing/laminating. The planar heat sinks 10 hold better and more stably on the PV structure. Clamping the first plate 10a into the gap of the frame 5 realizes an additional resistant connection to the PV laminate.

The cooling channels are configured in the second plate 10b and can be configured in particular with a small distance to the lateral edge of the second plate 10b, for example with a maximum distance of 3 to 4 mm. Despite this small distance to the lateral edge of the second plate 10b, the cooling channels 10c are not damaged when the layer stack 25 is clamped in the frame 5, since the second plate 10b is configured to be retracted with respect to the first plate 10a. The first plate 10a laterally advances over the second plate 10b to form the contact area 12.

The PVT module 100 according to the embodiment of FIG. 1 thus comprises a particularly resistant connection of the layers of the layer stack 25.

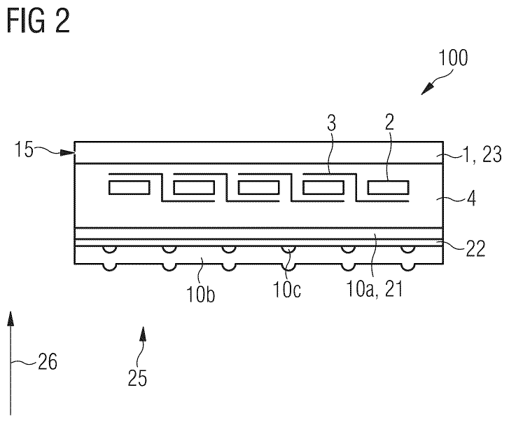

FIG. 2 shows the PVT module 100 according to a further embodiment. The PVT module 100 according to FIG. 2 essentially originates from the PVT module 100 according to FIG. 1. However, the planar heat sink 10, in particular, is configured differently.

The first plate 10a, which is in contact with the lamination film 4 of the solar cells 2, is not configured from aluminum or glass. The first plate 10a comprises a foil 21 or consists of the foil 21 or is formed from the foil 21. The foil 21 is in particular an inorganic foil, for example a plastic foil, in particular a PET foil.

The foil 21 closes the cooling channels 10c of the second plate 10b. In addition, the foil 21 connects the second plate 10b to the PV laminate, in particular to the solar cells 2. In addition, the foil 21 contributes to the electrical insulation between the second plate 10b and the solar cells 2.

The foil 21 and the second plate 10b are connected to one another by an adhesive bond 22. Since no soldering process takes place for the connection of the two plates 10a, 10b of the planar heat sink 10, the second plate 10b can extend to the edge 15 of the PVT module 100, unlike in the embodiment of FIG. 1. The cooling channels 10c can be sufficiently far away from the edge 15 to form the frame 5 and the clamp connection 5c in such a way that the cooling channels 10c are not damaged. The connection between the second plate 10b and the first plate 10a, which is configured as a foil 21, is reliably realized by the adhesive bond 22. The planar heat sink 10 thus consists, for example, of a PET-aluminum adhesive composite. It is also possible to provide the second plate 10b made of glass.

The adhesive bond 22 and the adhesive used are selected so that the second plate 10b is sufficiently strongly bonded to the foil 21, for example, to withstand an overpressure of 0.5 bar, at which pressure the coolant typically flows through the cooling channels 10c. The foil 21 is configured and selected so that it is resistant to the coolant, which is, for example, a glycol-water mixture. The foil 21 is configured so that the foil serves as a moisture barrier and does not allow moisture to reach the solar cells 2.

In the manufacturing process, it is possible to laminate the planar heat sink 10 with the foil 21 directly in a single lamination process together with the solar cells 2 and the lamination film 4. In particular, this saves on the rear wall film 6 according to the embodiment of FIG. 1. This saves costs due to the material savings and the additional lamination step and/or gluing process that is no longer required during production.

It is also possible to replace the front glass 1 with a front coating 23. This consists, for example, of a further foil or a transparent varnish layer. The additional foil is a flexible transparent foil, for example a PET foil. The front coating 23 makes a lightweight PVT module 100 possible. Furthermore, the PVT module 100 is easier to manufacture because there are no longer any different expansion coefficients between the front glass 1 and the second plate 10b made of aluminum to compensate for.

It is also possible, in the embodiment according to FIG. 1, to provide the front coating 23 instead of the front glass 1 and the planar heat sink 10 with the first plate 10a made of aluminum or glass. Thus, different combinations of the embodiments of FIGS. 1, 2 and 3 are possible and covered by this disclosure.

The PVT module 100 with the foil 21 and the front coating 23 made of a single foil can be produced by a single lamination, in which the solar cells 2, the foil 23, the lamination film 4 and the foil 21 are connected to the second plate 10b in a single step. EVA is preferably used as the lamination film.

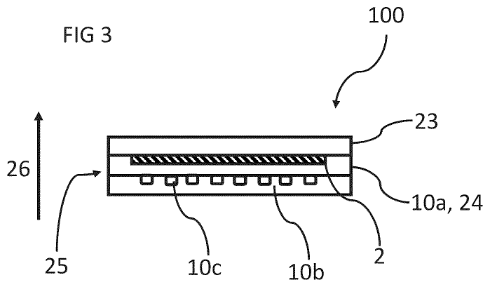

FIG. 3 shows the photovoltaic-thermal module 100 according to a further embodiment. Instead of the front glass 1, the PVT module 100 according to FIG. 3 comprises the front coating 23 made of a clear varnish. Such a clear varnish, which is sufficiently stable against weather, UV radiation and other influences over its entire service life, is known, for example, from the automotive industry.

The solar cells 2 are no longer embedded in the lamination film 4, but in a varnish layer 24. The varnish layer 24 surrounds and secures the solar cells 2. The varnish layer 24 is applied in such a way that the irradiation side of the solar cells 2 in particular is not covered by the varnish layer 24. The varnish layer 24 transforms and surrounds the solar cells 2 so that they are sufficiently mechanically stabilized. In addition, the varnish layer 24 acts as an adhesive or adhesion layer for bonding the second plate 10b. The varnish layer 24 thus also serves as the first plate 10a. The varnish layer 24 thus fulfills the function of the lamination film 4 and the first plate 10a in the embodiment according to FIG. 1.

The cooling channels 10c are formed in the second plate 10b between the second plate 10b and the varnish layer 24. The front coating 23, in particular the clear varnish, is sprayed onto the side of the solar cells 2 facing away from the second plate 10b.

The embodiment of the PVT module 100 according to FIG. 3 can thus be produced without a lamination step. In addition, cost-intensive materials such as lamination films and/or Tedlar films or adhesion-promoting films and layers can be saved. The production is significantly simplified and the process steps for production are reduced and thus the process chain is simplified. For production, the embedding varnish layer 24 is applied to the second plate 10b. The solar cells 2 are embedded in the varnish layer 24. The varnish layer 24 hardens. The varnish for the front coating 23 is then applied. The PVT module 100 is now complete. A glass front cover is not necessary. Its production saves a lot of resources and energy. The PVT module 100 is very lightweight. The PVT module 100 is cost-effective.

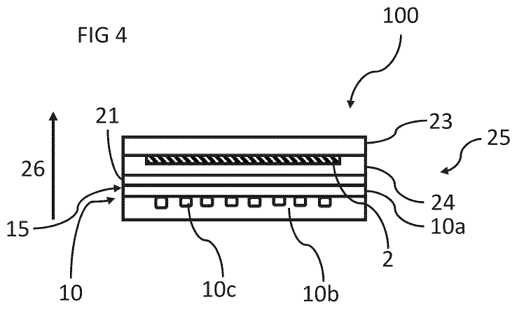

FIG. 4 shows the photovoltaic-thermal module 100 according to a further embodiment. The PVT module 100 comprises the varnish layer 24, which attaches and surrounds the solar cells 2. The varnish layer 24 is applied in such a way that in particular the irradiation side of the solar cells 2 is not covered by the varnish layer 24. The varnish layer 24 forms around and surrounds the solar cells 2, so that they are sufficiently mechanically stabilized. The varnish layer 24 thus fulfills the functionality of the lamination film 4 in particular. In addition, the PVT module 100 comprises the front coating 23 of a clear varnish.

The planar heat sink 10 comprises, in particular, two thin aluminum plates 10a, 10b that are connected to each other, for example soldered together. The channel structure with the plurality of cooling channels 10c is stamped into the second plate 10b by a punching process. The first plate 10a is connected to the varnish layer 24. The second plate 10b extends to the edge 15 of the PVT module 100 as in the embodiment shown in FIGS. 2 and 3. In further embodiments, the second plate 10b is set back as in the embodiment shown in FIG. 1, so that the second plate 10a is configured with the second region 13, which is not covered by the second plate 10b.

According to the embodiment shown in FIG. 4, a foil 21, in particular a PET foil, is provided between the first plate 10a and the varnish layer 24. The foil 21 serves as electrical insulation between the planar heat sink 10 and the solar cells 2. According to further embodiments, the foil 21 is dispensed with, in particular if the varnish layer 24 itself is sufficiently electrically insulating. In this embodiment, the first plate 10a is attached directly to the varnish layer 24.

The embodiment of the PVT module 100 according to FIG. 4 can thus be produced without a lamination step. In addition, cost-intensive materials such as lamination films and/or Tedlar films or adhesion-promoting films and layers can be saved. The glass front cover can be dispensed with. The PVT module 100 can be manufactured easily and reliably because there are no longer any different expansion coefficients between the front glass 1 and the aluminum planar heat sink 10 to compensate for. It is also possible to embed the solar cells 2 in the lamination film 4, as explained in connection with FIG. 1. The planar heat sink 10 serves as a mechanical support and the front coating 23 made of clear varnish covers the solar cells 2 on the top.

The PVT modules 100 described here can be used with solar cells 2 of all types, for example crystalline or bifacial crystalline modules or thin-film modules. Furthermore, the following areas of application can be considered for the modules 100: rooftop, industry, open space, low-temperature heating networks, floating systems, large open space solar parks, especially in hot areas such as the USA, India, Spain, Arabia, Australia, Chile.

The PVT module 100 according to the various embodiments is comparatively cost-effective to produce. Process times and manufacturing complexity can be reduced. This leads to increased economic efficiency of the PVT modules 100, especially in contrast to conventional PVT modules with copper pipes.

The PVT module 100 according to the various embodiments is characterized by improved reliability and quality due to the double joint connection by gluing/lamination and clamping in the frame 5. In addition, significant simplifications in the production process are possible. The use of expensive materials can be significantly reduced. Lower costs and higher economic efficiency are thus possible.

1.-13. (canceled)

14. A photovoltaic-thermal module comprising:
a plurality of solar cells; and
a planar heat sink based on at least one inorganic material and including a plurality of cooling channels,
wherein the planar heat sink comprises two plates between which the cooling channels are located,
wherein a first plate of the plates, facing the solar cells, is flat,
wherein the cooling channels are defined by a second plate of the plates, the second plate facing away from the solar cells, and
wherein the second plate is arranged on a main surface of the first plate such that a first region of the first plate is covered by the second plate and a second region of the first plate is free of the second plate.

15. The photovoltaic-thermal module according to claim 14, wherein the first plate extends over a larger area than the second plate.

16. The photovoltaic-thermal module according to claim 14, wherein the second region of the first plate is arranged so as to extend around the second plate.

17. The photovoltaic-thermal module according to claim 14, further comprising a support frame mechanically supporting the photovoltaic-thermal module, wherein the support frame is in contact with the second region of the first plate.

18. The photovoltaic-thermal module according to claim 17, wherein the support frame clamps the solar cells and the first plate together.

19. A photovoltaic-thermal module comprising:
a plurality of solar cells;
a planar heat sink comprising:
a plurality of cooling channels; and
two plates between which the cooling channels are located,
wherein a first plate of the plates faces the solar cells,
wherein the cooling channels are defined by a second plate of the plates facing away from the solar cells, and
wherein the first plate comprises a foil and/or a varnish.

20. The photovoltaic-thermal module according to claim 19, wherein the foil and/or the varnish and the second plate are connected to one another by an adhesive bond.

21. The photovoltaic-thermal module according to claim 19, wherein the foil and/or the varnish is arranged directly on the solar cells.

22. The photovoltaic-thermal module according to claim 19, wherein the first plate is formed by the foil and/or the varnish.

23. The photovoltaic-thermal module according to claim 19, wherein the solar cells are embedded in the varnish.

24. The photovoltaic-thermal module according to claim 23, wherein the photovoltaic-thermal module includes a layer stack comprising, in a stacking direction:
the second plate defining the cooling channels,
the varnish, which is configured as a layer and in which the solar cells are embedded, and
a front coating covering the varnish.

25. The photovoltaic-thermal module according to claim 19, further comprising a front coating arranged on a side of the solar cells facing away from the planar heat sink and covering the solar cells, wherein the front coating is formed by the foil or the varnish.

26. The photovoltaic-thermal module according to claim 25, wherein the photovoltaic-thermal module includes a layer stack comprising, in a stacking direction:
the second plate defining the cooling channels,
the varnish, which is configured as a layer and in which the solar cells are embedded, and
the front coating covering the varnish.

27. A photovoltaic-thermal module comprising:
a plurality of solar cells embedded in a varnish layer; and
a planar heat sink based on at least one inorganic material and including a plurality of cooling channels,
wherein the planar heat sink comprises two plates between which the cooling channels are located,
wherein a first plate of the plates faces the solar cells and is flat,
wherein the cooling channels are defined by a second plate of the plates, the second plate facing away from the solar cells, and
wherein the planar heat sink is attached to the varnish layer.
